(19) United States
(12) Patent Application Publication
(10) Pub. No.: US 2025/0273592 A1
(43) Pub. Date: Aug. 28, 2025

(54) PARTIALLY SHIELDED SEMICONDUCTOR DEVICE AND METHOD FOR FORMING THE SAME

(71) Applicant: STATS ChipPAC Pte. Ltd., Singapore (SG)

(72) Inventors: JinHee JUNG, Incheon (KR); ChangOh KIM, Incheon (KR); WooSoon KIM, Incheon (KR)

(21) Appl. No.: 19/055,522

(22) Filed: Feb. 18, 2025

(30) Foreign Application Priority Data
Feb. 22, 2024 (CN) 202410197630.6

(51) Int. Cl. H01L 23/552; H01L 21/56; H01L 23/26; H01L 23/31; H01L 25/18

(52) U.S. Cl. CPC H01L 23/552; H01L 21/56; H01L 23/26; H01L 23/315; H01L 25/18

(57) ABSTRACT

A partially shielded semiconductor device and a method for forming the same are provided. The method includes: providing a semiconductor package; dispensing an ink composition to form a barrier structure on a surface of the semiconductor package, wherein the barrier structure divides the surface of the semiconductor package into at least a first portion and a second portion; dispensing a fluid including a metal precursor onto the first portion of the surface of the semiconductor package, wherein the barrier structure prevents the fluid flowing to the second portion of the surface of the semiconductor package; and curing the fluid to form an electromagnetic interference (EMI) shield.

### TECHNICAL FIELD

The present application generally relates to semiconductor technology, and more particularly, to a partially shielded semiconductor device and a method for forming the same.

### BACKGROUND OF THE INVENTION

The semiconductor industry is constantly faced with complex integration challenges as consumers want their electronics to be smaller, faster and higher performance with more and more functionalities packed into a single device. Recently, millimeter Wave (mmWave) modules are introduced for the fifth-generation (5G) communication technology, and most of them may be partially covered by an electromagnetic interference (EMI) shield because the other region of the mmWave modules may be left uncovered for antennas or for other purposes. However, the conventional method for forming a partially shielded semiconductor device is complex, resulting in excess cost and low reliability.

Therefore, a need exists for a partially shielded semiconductor device with reduced cost.

### SUMMARY OF THE INVENTION

An objective of the present application is to provide a semiconductor device with low cost and/or improved reliability.

According to an aspect of the present application, a method for forming a partially shielded semiconductor device is provided. The method may include: providing a semiconductor package; dispensing an ink composition to form a barrier structure on a surface of the semiconductor package, wherein the barrier structure divides the surface of the semiconductor package into at least a first portion and a second portion; and dispensing a fluid including a metal precursor onto the first portion of the surface of the semiconductor package, wherein the barrier structure prevents the fluid flowing to the second portion of the surface of the semiconductor package; and curing the fluid to form an electromagnetic interference (EMI) shield.

According to another aspect of the present application, a partially shielded semiconductor device is provided. The partially shielded semiconductor device may include: a semiconductor package; a barrier structure formed on a surface of the semiconductor package, wherein the barrier structure is made of an ink composition and divides the surface of the semiconductor package into at least a first portion and a second portion; and an electromagnetic interference (EMI) shield formed on the first portion of the surface of the semiconductor package but not on the second portion of the surface of the semiconductor package, wherein the EMI shield is made of a fluid including a metal precursor.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating a partially shielded semiconductor device.

FIGS. 2A to 2E are cross-sectional views illustrating various steps of a method for forming a barrier structure with an ink composition according to an embodiment of the present application.

FIGS. 3A to 3E are perspective views illustrating various steps of a method for forming a barrier structure with an ink composition according to an embodiment of the present application.

FIGS. 4A to 4D are cross-sectional views illustrating various steps of a method for forming a partially shielded semiconductor device according to an embodiment of the present application.

FIG. 5 is a cross-sectional view illustrating a partially shielded semiconductor device according to an embodiment of the present application.

FIG. 6 is a cross-sectional view illustrating a partially shielded semiconductor device according to another embodiment of the present application.

FIG. 7 is a cross-sectional view illustrating a partially shielded semiconductor device according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

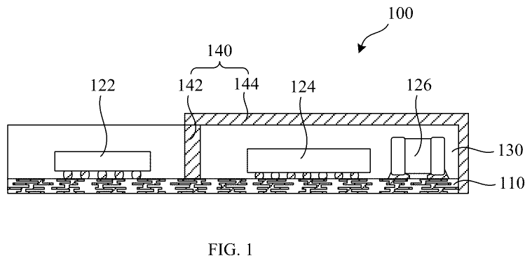

FIG. 1 illustrates a cross-sectional view of a partially shielded semiconductor device 100. The device 100 may include a substrate 110, a plurality of electronic components 122, 124 and 126 mounted on the substrate 110, and an encapsulant 130 covering the electronic components 122, 124 and 126. As the plurality of electronic components 122, 124 and 126 may have different functions, electromagnetic interferences may exist between the electronic components 122, 124 and 126, which may be desired to be removed or reduced. Furthermore, electromagnetic interferences from the exterior environment may also be desired to be removed or reduced for some or all of the electronic components 122, 124 and 126 or the other components mounted on the substrate 110 such as passive components (e.g., inductors, capacitors). As an example, an EMI shield 140 may be formed to cover the electronic components 124 and 126 that are susceptible to or generate EMI, radio frequency interference (RFI), harmonic distortion, or inter-device interferences. The EMI shield 140 may for example be composed substantially of metal material(s). In this example, the EMI shield 140 may include a first portion 142 filled in a trench of the encapsulant 130, and a second portion 144 covering an outer surface of the encapsulant 130. It can be appreciated that the EMI shield 140 may take any other suitable shapes and forms depending on the requirement of EMI reduction.

In a conventional method to form the EMI shield 140, a trench is first formed in the encapsulant 130, and then the trench is filled with a conductive material such as copper or aluminum to form the first portion 142 of the EMI shield 140. Afterwards, a masking tape is adhered on an area of the encapsulant 130 where the EMI shield is not needed, and a sputtering method or other similar vapor deposition method is employed to deposit the conductive material onto the encapsulant 130, as well as onto the masking tape. At last, the masking tape is stripped to remove the conductive material deposited thereon, i.e., the area covered by the masking tape can be uncovered by the conductive material, and the left part of the conductive material forms the second portion 144 of the EMI shield 140. As can be seen, the above method is complex, resulting in excess cost and low reliability.

To address at least one of the above problems, a method for making a partially shielded semiconductor device is provided in an aspect of the present application. In the method, an ink composition is dispensed on a surface of a semiconductor package to form a barrier structure. The barrier structure may divide the surface of the package into at least a first portion and a second portion, and when a fluid including a metal precursor or similar materials is dispensed onto the first portion of the surface of the package, the barrier structure can prevent the fluid from flowing across it to the second portion of the surface of the package. Accordingly, the second portion of the surface of the package may not be covered by the fluid including the metal precursor. Then, the fluid may be cured to form an EMI shield partially covering the semiconductor package.

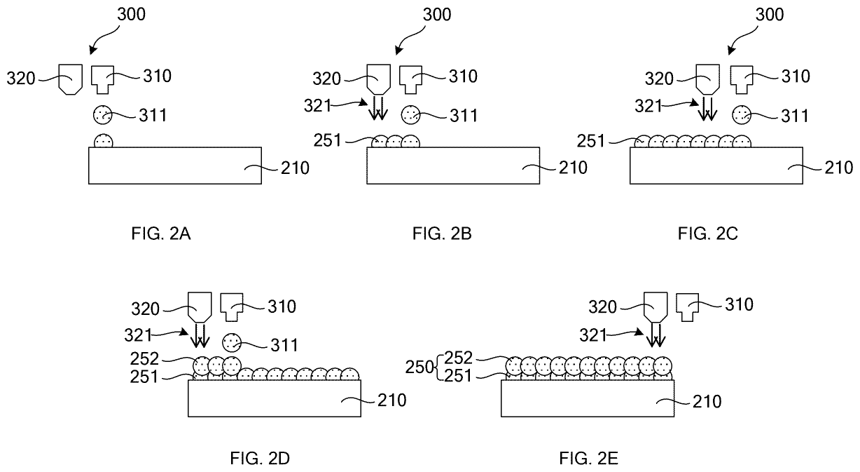

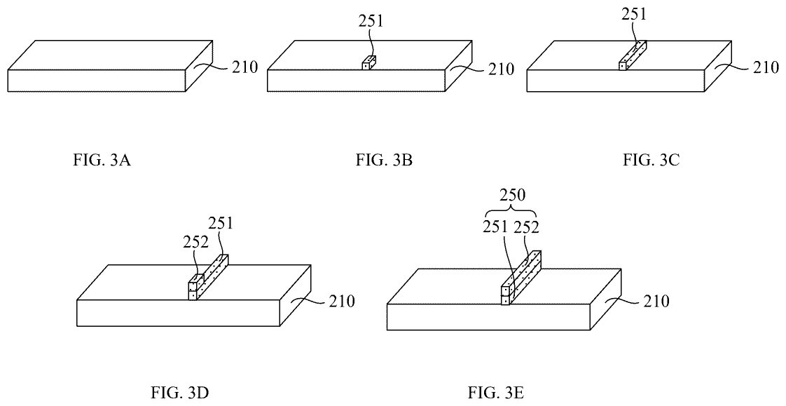

Referring to FIGS. 2A to 2E and FIGS. 3A to 3E, various steps of a method for forming a barrier structure with an ink composition are illustrated according to an embodiment of the present application. FIGS. 2A to 2E are cross-sectional views illustrating various steps of the method, and FIGS. 3A to 3E are corresponding perspective views of the steps. In the following, the method will be described with reference to FIGS. 2A to 2E and FIGS. 3A to 3E in more details.

Referring to FIG. 2A, an inkjet apparatus 300 is provided. The inkjet apparatus 300 may at least include a dispensing nozzle 310 configured for dispensing an ink composition and a light source 320 configured for irradiating a light beam with a predetermined intensity.

In some embodiments, the ink composition may include a photocurable material and a thermosetting material. The photocurable material may include a curable compound having a (meth) acryloyl group, a curable compound having a vinyl group, a curable compound having a maleimide group, or other suitable materials. The thermosetting material may include an organic acid, an amine compound, an amide compound, a hydrazide compound, an imidazole compound, an imidazoline compound, a phenol compound, a urea compound, a polysulfide compound, an acid anhydride, or other suitable materials. For example, the ink composition may be Sekisui 3D inkjet materials commercially available from SEKISUI CHEMICAL CO., LTD. However, the present application is not limited to the above examples. In some other embodiments, the ink composition may only include a photocurable material or a thermosetting material.

Referring to FIGS. 2A and 3A, a substrate 210 is provided, and the dispensing nozzle 310 of the inkjet apparatus 300 is controlled to produce droplets 311 of the ink composition in the order of several to several tens of micrometers (for example, 20 μm) in diameter, which will be projected towards the substrate 210. The substrate 210 may include a semiconductor package, a semiconductor wafer, a semiconductor wafer after dicing, a printed circuit board or any other support member for mounting a semiconductor element. By moving the substrate 210 or the dispensing nozzle 310 relative to each other, the droplets 311 can be dispensed onto a surface of the substrate 210 at a location where the barrier structure is to be formed.

Referring to FIGS. 2B and 3B, the substrate 210 is moved until the droplets 311 dispensed onto the substrate 210 in FIG. 2A are right below the light source 320 and thus can be irradiated by a light beam from the light source 320. Alternatively, the light source 320 of the inkjet apparatus 300 may be moved to a position right above the droplets 311. Then, the light source 320 is controlled to irradiate a light beam 321 such as ultraviolet (UV) light with a predetermined intensity (for example, >5000 mW/cm²), which can be used to cure the material in the droplets 311. After the droplets 311 are cured by the light beam 321 and solidify, a first barrier structure 251 is formed on the surface of the substrate 210. In a specific example, each cured droplet 311 may have a spherical shape with a width of 50 μm and a height of 5 μm. It should be noted that while the light source 320 is controlled to cure the droplets 311 dispensed, the dispensing nozzle 310 continues to dispense more droplets 311 onto other positions of the surface of the substrate 210. Since the light source 320 and the dispensing nozzle 310 move simultaneously relative to the substrate 210, the time the dispensing nozzle 310 stays above a position over the substrate 210 for liquid dispensing should be sufficient for the time for UV curing, otherwise the liquid droplets 311 may not be able to be cured well.

Referring to FIGS. 2C and 3C, the substrate 210 is moved until the droplets 311 dispensed in FIG. 2B (i.e., a portion of the droplets 311 different from but adjacent to the droplets 311 dispensing in FIG. 2A) are right below the light source 320, and the light source 320 is controlled to cure the droplets 311 dispensing in FIG. 2B. By continuously moving the substrate 210 relative to the dispensing nozzle 310, dispensing the droplets 311 of the ink composition and curing the droplets 311 with light irradiation, the first barrier structure 251 can be formed on the substrate 210, for example, across a width of the substrate 210. As the inkjet apparatus 300 can accurately control the position and/or the dispensing time of the droplets 311, the first barrier structure 251 can be directly formed at a desired area with a desired shape without any mask, or any photolithography process.

Referring to FIGS. 2D and 2E and FIGS. 3D and 3E, a second barrier structure 252 is formed on the first barrier structure 251 which has been cured and solidified to obtain a barrier structure 250 with a desired height. The second barrier structure 252 may be formed using a process similar as that described with reference to FIGS. 2A to 2C and FIGS. 3A to 3C, and will not be elaborated herein. It can be appreciated that the second barrier structure 252 may have the same layout as the first barrier structure 251 or a different layout from the first barrier structure 251. In some other embodiments, more layers of barrier structures may be formed using the process similar as that shown in FIGS. 2A to 2C and FIGS. 3A to 3C to obtain a stack of barrier structures with a desired height.

In some embodiments, when the ink composition includes a thermosetting material, the barrier structure 250 may be cured under a predetermined temperature for a predetermined period (for example, under 170° C. for 1 hour) which depends on properties of the thermosetting material.

In the above embodiment, an inkjet system is used to form the barrier structure 250. However, the present application is not limited thereto. In some other embodiments, the barrier structure 250 may be formed by an aerosol jetting system, an electrohydrodynamic (EHD) jetting system, or other directly dispensing systems.

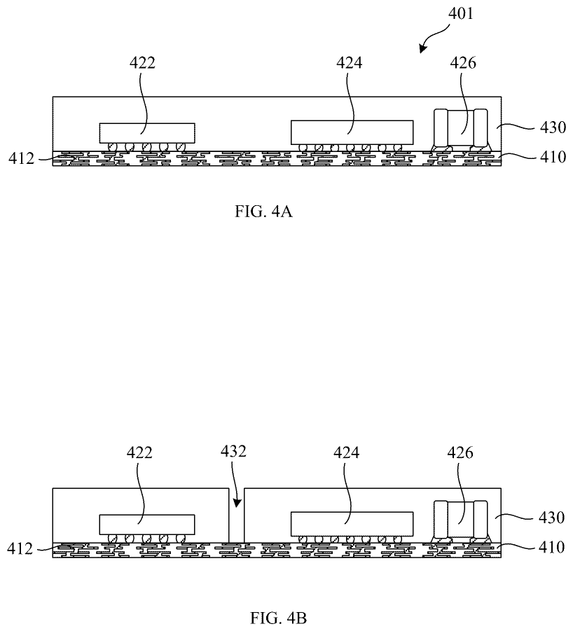

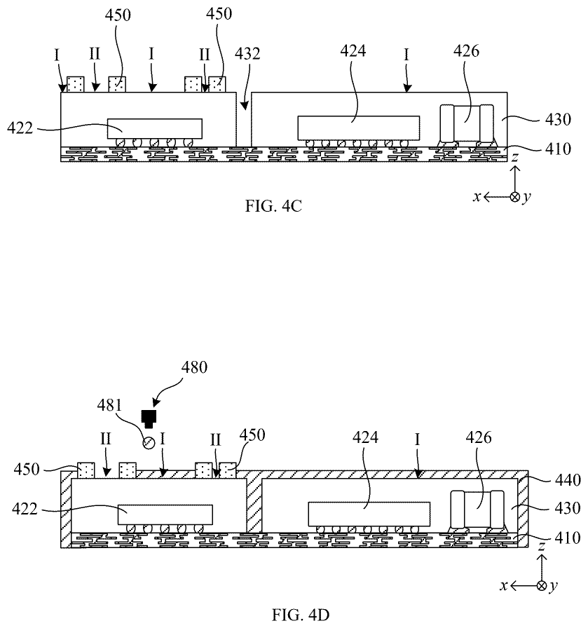

Referring to FIGS. 4A to 4D, various steps of a method for forming a partially shielded semiconductor device are illustrated according to an embodiment of the present application. In the following, the method will be described with reference to FIGS. 4A to 4D in more details.

Referring to FIG. 4A, a semiconductor package 401 is provided. Specifically, the semiconductor package 401 may include a substrate 410 that provides support and connectivity for electrical components and devices. By way of example, the substrate 410 may include a printed circuit board (PCB), a carrier substrate, a semiconductor substrate with electrical interconnections, a ceramic substrate, a laminate interposer, a strip interposer, a leadframe, or other suitable substrates. The substrate 410 may include any structure on or in which an integrated circuit system can be fabricated. In the example shown in FIG. 4A, the substrate 410 includes redistribution structures 412 having one or more dielectric layers and one or more conductive layers between and through dielectric layers. The conductive layers may define pads, traces and plugs through which electrical signals or voltages can be distributed horizontally and vertically across the redistribution structures 412. It could be appreciated that, the redistribution structures 412 may be implemented in various structures and types, but aspects of the present application are not limited to the above example.

As shown in FIG. 4A, a plurality of electronic components 422, 424 and 426 may be mounted on a top surface of the substrate 410. The electronic components 422, 424 and 426 may include any of a variety of types of semiconductor dice, semiconductor packages, or discrete devices. For example, the electronic components 422, 424 and 426 may include a digital signal processor (DSP), a microcontroller, a microprocessor, a network processor, a power management processor, an audio processor, a video processor, an RF circuit, a wireless baseband system-on-chip (SoC) processor, a sensor, a memory controller, a memory device, an application specific integrated circuit, etc. An encapsulant 430 is formed on the top surface of the substrate 410 and encapsulates the electronic components 422, 424 and 426. The encapsulant 430 may be made of polymer composite material, such as epoxy resin with filler, epoxy acrylate with filler, or polymer with proper filler, but the scope of this application is not limited thereto.

By way of example, the first electronic component 422 and the second electronic components 424 and 426 may have different functions, and electromagnetic interferences may exist between the electronic components 422, 424 and 426. Accordingly, an EMI shield may be formed in subsequent steps to cover the second electronic components 424 and 426 that are susceptible to or generate EMI.

Referring to FIG. 4B, a trench 432 is formed in the encapsulant 430 and between the first electronic component 422 and the second electronic components 424 and 426. The trench 432 may expose the substrate 410, and optionally a conductive pad of the redistribution structures 412.

In some embodiments, a laser ablation process may be employed to form the trench 432 in the encapsulant 430. The laser ablation process can be controlled by computer-aided design data, and therefore the size and depth of the trench 432 can be accurately controlled. In some other embodiments, the trench 432 may be formed by an etching process, or any other process known in the art so long as the encapsulant material can be partially removed as desired.

Referring to FIG. 4C, an ink composition is dispensed to form one or more barrier structures 450 on the top surface of the encapsulant 430. The barrier structures 450 divide the top surface of the encapsulant 430 into at least a first portion I and a second portion II. In a subsequent step, the EMI shield will be formed on the first portion I of the top surface of the encapsulant 430 but not on the second portion II of the top surface of the encapsulant 430.

The method for forming the barrier structures 450 may refer to the embodiments described with reference to FIGS. 2A to 2E and FIGS. 3A to 3E, and will not be elaborated herein. It can be understood that the barrier structures 450 shown in FIG. 4C are only examples. In some other embodiments, the barrier structures 450 may take other shapes (for example, a line, a ring shape, a rectangular shape, etc.) and have different heights.

Referring to FIG. 4D, a fluid including a metal precursor is dispensed onto the first portion I of the top surface of the encapsulant 430. In some embodiments, the metal precursor may include metal cations or metal particles such as silver, copper or gold. After the fluid is dispensed on the first portion I of the top surface of the encapsulant 430, the barrier structures 450 can prevent the fluid from flowing across them to the second portion II of the top surface of the encapsulant 430 as each barrier structure 450 may be higher (for example, 5 to 15 μm or even higher) than the fluid. Afterwards, the fluid may be cured to form an EMI shield 440.

In the example shown in FIG. 4D, an aerosol jetting system 480 may be used to dispense the fluid on the first portion I of the top surface of the encapsulant 430. The aerosol jetting system 480 can atomize the fluid via ultrasonic or pneumatic means, so as to produce droplets 481 in the order of one or more micrometers in diameter but generally less than ten micrometers in diameter. The droplets 481 may be entrained in a gas stream and delivered to a print head. At the print head, a sheath gas flow (for example, N₂ gas flow) may be introduced to focus the droplets 481 in a tightly collimated beam of material. Then, the combined gas streams may fly out of the print head through a converging nozzle that compresses the aerosol stream to a small diameter. Then, the jet of droplets 481 may fly out of the print head at a high velocity and impinge upon the first portion I of the top surface of the encapsulant 430. Thus, the fluid (i.e., droplets 481) can cover the first portion I of the top surface of the encapsulant 430 by moving the substrate 410 relative to the aerosol jetting system 480 (for example, along the x-axis direction and/or the y-axis direction shown in FIG. 4C) and continuously dispensing the droplets 481. Then, the fluid may be cured by light irradiation and/or heating to form the EMI shield 440, depending on properties of the fluid and the metal precursor.

In the above example, an aerosol jetting system 480 is used to form the EMI shield 440. However, the present application is not limited thereto. In some other embodiments, the EMI shield 440 may be formed by a spray system, an inkjet system, or other dispensing systems. In some embodiments, the EMI shield 440 may be formed by multiple dispensing techniques. For example, a spray system may be used to dispense the fluid including the metal precursor onto a region with a larger area (for example, the right part of the first portion I of the top surface of the encapsulant 430), while an inkjet system or an aerosol jetting system may be used to dispense the fluid onto a region with a smaller area (for example, the left part of the first portion I of the top surface of the encapsulant 430), so as to increase production capacity.

In some embodiments, when dispensing the fluid including the metal precursor, the substrate 410 can be moved, for example, along the z-axis direction shown in FIG. 4D, to adjust a distance between the encapsulant 430 and the nozzle of the dispensing system 480. Accordingly, as shown in FIG. 4D, the fluid including the metal precursor can be dispensed into the trench 432 and onto lateral surfaces of the encapsulant 430 and the substrate 410. Thus, after the fluid is cured, the EMI shield 440 may accommodate the second electronic components 424 and 426 thereunder, and be formed in desired positions adjacent to the first electronic components 422.

Compared with the EMI shield 140 shown in FIG. 1, the EMI shield 440 formed by the method described with reference to FIGS. 4A-4D has multiple shielding areas, but can be formed by reduced processes. Thus, the cost for fabricating the partially shielded semiconductor device is reduced, and the reliability is improved.

According to another aspect of the present application, a partially shielded semiconductor device is provided.

Referring to FIG. 5, a cross-sectional view of a partially shielded semiconductor device 500 is illustrated according to an embodiment of the present disclosure. The partially shielded semiconductor device 500 may include a semiconductor package, a plurality of barrier structures 550, and an electromagnetic interference (EMI) shield 540. For example, the semiconductor package may include a substrate 510, a first electronic component 522 and multiple second electronic components 524 and 526 mounted on the substrate 510, and an encapsulant 530 formed on the substrate 510 and encapsulating the first electronic component 522 and the second electronic components 524 and 526. The barrier structures 550 are formed on a top surface of the encapsulant 530. The barrier structure 550 are made of an ink composition and divide the top surface of the encapsulant 530 into at least a first portion I and a second portion II. The EMI shield 540 is formed on the first portion I of the top surface of the encapsulant 530 but not on the second portion II of the top surface of the encapsulant 530. The EMI shield 540 is made of a fluid including a metal precursor.

In some embodiments, the ink composition may include a photocurable material and/or a thermosetting material.

In some embodiments, a height of the barrier structure 550 is larger than a thickness of the EMI shield 540.

In some embodiments, a trench is formed in the encapsulant 530 and between the first electronic component 522 and the second electronic components 524 and 526. The EMI shield 540 may fill the trench in the encapsulant 530.

The partially shielded semiconductor device 500 can be formed by the steps illustrated in FIGS. 4A to 4D. Thus, more details about the partially shielded semiconductor device 500 may refer to the above method embodiments, and will not be elaborated herein.

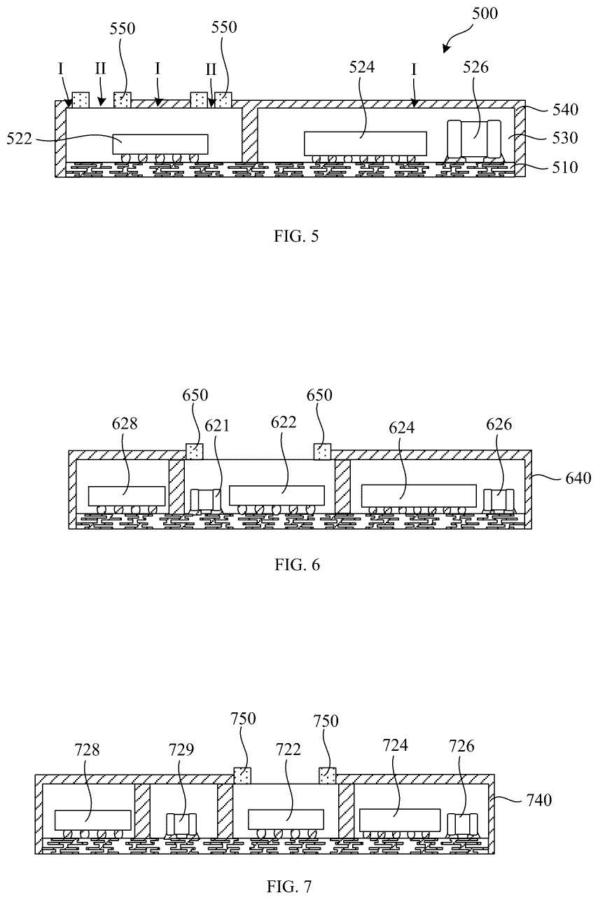

In the partially shielded semiconductor device 500 shown in FIG. 5, the second electronic components 524 and 526 is accommodated by the EMI shield 540. However, the present application is not limited thereto. In some other embodiments, there may be more shielded areas in the semiconductor devices. Referring to FIG. 6, by adjusting the configurations of barrier structures 650 and an EMI shield 640, two first electronic components 621 and 622 are not covered by the EMI shield 640, two second electronic components 624 and 626 are accommodated by a chamber of the EMI shield 640, and a third electronic component 628 is accommodated by another chamber of the EMI shield 640. Further, Referring to FIG. 7 which shows a partially shielded device according to another embodiment of the present application, by adjusting the configurations of barrier structures 750 and a EMI shield 740, a first electronic component 722 is not covered by the EMI shield 740, two second electronic components 724 and 726 are accommodated by a first chamber of the EMI shield 740, a third electronic component 728 is accommodated by a second chamber of the EMI shield 740, and a fourth electronic component 729 is accommodated by a third chamber of the EMI shield 740,.

While the partially shielded semiconductor device of the present application is described in conjunction with corresponding figures, it will be understood by those skilled in the art that modifications and adaptations to the partially shielded semiconductor device may be made without departing from the scope of the present invention.

The discussion herein included numerous illustrative figures that showed various portions of a partially shielded semiconductor device and a method for making the same. For illustrative clarity, such figures did not show all aspects of each example device. Any of the example devices and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a partially shielded semiconductor device, comprising:
providing a semiconductor package;
dispensing an ink composition to form a barrier structure on a surface of the semiconductor package, wherein the barrier structure divides the surface of the semiconductor package into at least a first portion and a second portion;
dispensing a fluid comprising a metal precursor onto the first portion of the surface of the semiconductor package, wherein the barrier structure prevents the fluid flowing to the second portion of the surface of the semiconductor package; and
curing the fluid to form an electromagnetic interference (EMI) shield.

2. The method of claim 1, wherein the ink composition comprises a photocurable material and/or a thermosetting material.

3. The method of claim 2, wherein dispensing the ink composition to form the barrier structure on the surface of the semiconductor package comprises:
dispensing the ink composition on the surface of the semiconductor package; and
curing the ink composition by light irradiation and/or heating to form the barrier structure.

4. The method of claim 1, wherein dispensing the ink composition to form the barrier structure on the surface of the semiconductor package comprises:
dispensing the ink composition by using an inkjet system or an aerosol jetting system.

5. The method of claim 1, wherein dispensing the fluid comprising the metal precursor onto the first portion of the surface of the semiconductor package comprises:
dispensing the fluid comprising the metal precursor by using a spray system, an inkjet system, or an aerosol system.

6. The method of claim 5, wherein dispensing the fluid comprising the metal precursor onto the first portion of the surface of the semiconductor package further comprises:
moving the semiconductor package to adjust a distance between the semiconductor package and a nozzle dispensing the fluid.

7. The method of claim 1, wherein a height of the barrier structure is larger than a thickness of the fluid dispensed on the first portion of the surface of the semiconductor package.

8. The method of claim 1, wherein the semiconductor package comprises:
a substrate;
a first electronic component and a second electronic component mounted on the substrate; and
an encapsulant formed on the substrate and encapsulating the first electronic component and the second electronic component, wherein the surface of the semiconductor package comprises a top surface of the encapsulant.

9. The method of claim 8, further comprising:
forming a trench in the encapsulant and between the first electronic component and the second electronic component.

10. The method of claim 9, wherein dispensing the fluid comprising the metal precursor onto the first portion of the surface of the semiconductor package comprising:
dispensing the fluid comprising the metal precursor into the trench.

11. A partially shielded semiconductor device, comprising:
a semiconductor package;
a barrier structure formed on a surface of the semiconductor package, wherein the barrier structure is made of an ink composition and divides the surface of the semiconductor package into at least a first portion and a second portion; and
an electromagnetic interference (EMI) shield formed on the first portion of the surface of the semiconductor package but not on the second portion of the surface of the semiconductor package, wherein the EMI shield is made of a fluid comprising a metal precursor.

12. The partially shielded semiconductor device of claim 11, wherein the ink composition comprises a photocurable material and/or a thermosetting material.

13. The partially shielded semiconductor device of claim 11, wherein a height of the barrier structure is larger than a thickness of the EMI shield.

14. The partially shielded semiconductor device of claim 11, wherein the semiconductor package comprises:
a substrate;
a first electronic component and a second electronic component mounted on the substrate; and
an encapsulant formed on the substrate and encapsulating the first electronic component and the second electronic component, wherein the surface of the semiconductor package comprises a top surface of the encapsulant.

15. The partially shielded semiconductor device of claim 14, further comprising:
a trench formed in the encapsulant and between the first electronic component and the second electronic component.

16. The partially shielded semiconductor device of claim 15, wherein the EMI shield fills the trench in the encapsulant.
